(19) United States
(12) Patent Application Publication
(10) Pub. No.: US 2002/0008259 A1
(43) Pub. Date: Jan. 24, 2002

(54) METHOD OF FABRICATING A SEMICONDUCTOR DEVICE WITH AN OPEN DRAIN INPUT/OUTPUT TERMINAL

(76) Inventors: BYUNG-SUP SHIM, SEOUL (KR); CHIL-HEE CHUNG, SEOUL (KR)

Correspondence Address: JONES VOLENTINE STEINBERG & WHITT LLP, 12200 SUNRISE VALLEY DRIVE, SUITE 150, RESTON, VA, 20191

(21) Appl. No.: 09/302,509

(22) Filed: Apr. 30, 1999

(30) Foreign Application Priority Data
May 4, 1998 (KR) 98-15974

(51) Int. Cl. H01L 29/76; H01L 29/94; H01L 31/062; H01L 31/113; H01L 31/119

(52) U.S. Cl. 257/288

(57) ABSTRACT

A semiconductor device is provided having an open drain input/output terminal. The device is formed on a semiconductor substrate of a first conductivity type, having active regions defined by a field oxide layer. A gate insulating layer is formed over the active regions such that it is thicker in an open drain I/O formation area than in a logic formation area. A gate electrode is formed over a predetermined portion of the gate insulating layer, and a second conductivity type junction region for a source/drain is formed in the substrate on both sides of the gate electrode. A field insulating doping layer is formed under the field oxide layer such that it overlaps the junction region in the logic formation part, and is spaced apart from the junction region in the open drain I/O formation part. A second conductivity type impurity region is formed as a channel region under the gate electrode of an enhancement transistor formation part in the open drain I/O formation area. A first conductivity type impurity region formed between the second conductivity type impurity regions.

This application relies for priority upon Korean Patent Application No. 98-15974, filed on May 4, 1998, the contents of which are herein incorporated by reference in their entirety.

### BACKGROUND OF THE INVENTION

1. Field of the Invention

The present invention relates to a semiconductor device and its fabricating method. More particularly, the present invention relates to a semiconductor device and its fabricating method, provided with an open drain input/output (I/O) terminal that enhances the junction B•V (Breakdown Voltage) characteristic of the transistors of the open drain I/O terminal and the insulating characteristic of a gate insulating layer.

2. Discussion of Related Art

In general, an I/O terminal of a semiconductor device performs the following functions: (1) it operates the external device with an internal pull-up resistor or a push-pull circuit; (2) it operates the external device with the external power; and (3) it operates the internal circuit with the external signal. Among these functions, either (1) or (2) may be selectively realized according to its own usage. Generally, an open drain I/O terminal performs the functions (2) and (3).

The function is generally switched from (1) to (2) only when the current path is cut off by breaking down the node “C” or converting the depletion transistor that is used for a pull-up resistor into an enhancement transistor through the impurity ion implanting process after forming a gate.

In the open drain I/O terminal, when controlling the device with an external high voltage, if the chip power and the external high voltage are applied to both the pull up resistor terminals of the pull-up resistor I/O terminal, the power flows through the pull-up resistor and the external device is out of control. Therefore, in order to break down the depletion transistor used for a pull-up resistor through an impurity ion implanting process, the depletion transistor is converted into an enhancement transistor.

FIG. 1 is a circuit diagram showing the structure of an open drain input/output terminal of a related semiconductor device fabricated in accordance with the method described above. Referring to FIG. 1, the conventional open drain I/O terminal is structured roughly as follows. Two transistors are used: an n-channel open drain transistor “A,” and an n-channel depletion transistor “B”, i.e., an enhancement transistor formed through an impurity ion implanting process after the gate formation step.

These two transistors A and B have their gates respectively connected to each of the internal logic circuits 10a and 10b. The source of the open drain transistor A is connected to an internal supply voltage V_{dd}, and the source of the depletion transistor B is connected to ground. The open drain transistor A and the depletion transistor B are connected in series, with their drains being commonly connected an input/output pad 20. An analog integrated circuit, which is made by a process different from the MOS type large scale integration (LSI), is connected to the pad 20 to provide the pad with an external high voltage. Accordingly, the external high voltage is applied to the drains of each of the open drain transistor A and the depletion transistor B.

In addition, an input of an inverter “D” is also connected to the pad 20 so that the inverter D is also supplied with the external high voltage. In FIG. 1, the reference letter “C” designates the short point in the open drain circuit and the reference letter “E” designates the external device.

FIGS. 2a to 2e illustrate the procedures of fabricating a semiconductor device with an open drain input/output terminal. As shown in FIGS. 2a to 2e, a semiconductor device having the open drain I/O terminal described above may be fabricated in the following five steps.

In the first step, as illustrated in FIG. 2a, a terminal oxidation layer 102 and an anti-oxidation layer 104 of an oxide are formed, in turn, on a semiconductor substrate 100 of a first conductivity type, e.g., p-type. A lightly-doped first conductivity type impurity ion is then field-implanted into the overall surface of the substrate, selectively into the active region of the substrate 100. In FIG. 2a, the region where the impurity ion is implanted, i.e., a field insulating doping region, is marked by the letter “x.” The reference number “I” denotes a logic formation area, while reference number “II” designates the open drain I/O formation part. The open drain formation part II itself includes a transistor formation part “II₁” and an enhancement transistor formation part “11₂”.

In the second step, as illustrated in FIG. 2b, an oxide process is performed using the anti-oxidation layer 104 as a mask to thereby form a field oxide layer 106 having a field insulating doping layer 108 on the device isolating region. The anti-oxidation layer 104 is removed and a process of implanting ion for controlling the threshold voltage (Vₜₕ) is performed.

In the third step, as illustrated in FIG. 2c, a portion of the terminal oxide layer 102 in the active region is removed and a sacrificial oxide layer 110 is then formed in the active region. A photoresist layer of a predetermined thickness is then formed on the overall surface of the substrate. Using the photo-etching process, the photoresist layer is selectively etched to expose the surface of the sacrificial oxide layer 110 in the enhancement transistor formation part II₂, thus forming a first photoresist pattern 112. A lightly-doped second conductivity type impurity ion, e.g., of n-type, is implanted into the exposed sacrificial oxide layer 110 to form a second-conductivity-type impurity region 114 that may be used for the depletion region of the substrate 100.

In the fourth step, as illustrated in FIG. 2d, the first photoresist pattern 112 and the sacrificial oxide layer 110 are removed in sequence, and a gate insulating layer 116 is formed on the substrate 100. A gate electrode 118 is then formed on a predetermined portion on the gate insulating layer 116 over the logic formation area I and the open drain I/O terminal formation area II. Using the electrode 118 as a mask, a heavily doped second conductivity type impurity ion is implanted into the substrate 100 on both sides of each gate electrode 118, forming a junction region 120 which may be used as a source and drain for each of the gates.

In the fifth step, as illustrated in FIG. 2e, another photoresist layer is formed on the overall surface of the gate insulating layer 116 including the field insulating layer 106 and the gate electrodes 118. Using a photo-etching process, the layer is selectively etched to expose a predetermined portion of the gate electrode 118 in the enhancement transistor formation part II₂, thus forming a second photoresist pattern 119. A lightly-doped first conductivity type impurity ion is then implanted into the exposed gate electrode 118 with a high energy, thus forming a first-conductivity-type impurity region 122 in the second-conductivity-type impurity region 114.

As a result of this five-step process, a general logic transistor is formed in the logic formation area I and an open drain transistor or enhancement transistor is formed in the open drain I/O terminal formation area II. The photoresist pattern is then removed and an insulating interlayer having a contact hole (not shown) is formed thereon. A metallization (not shown) is then formed to join the gate electrode 118 and the junction region 120, completing the process.

However, the related fabricating procedure described above causes a number of problems as set forth below.

First, as semiconductor devices become more integrated and individual circuit elements are reduced in size, a design rule of each device is also minimized and the gate insulating layer 116 becomes thinner to realize a semiconductor device of a high performance. In case of transistors in the logic formation area I, a thinner gate insulating layer 116 is not a problem. The operational voltage of the circuits in the logic formation area I is 3.3 V or 5.0 V and thus it is not problematic for operating the device.

However, in the case of the transistors A and B in the open drain I/O terminal formation area II, the thinner gate insulating layer 116 can lead to problems. The voltage used for operating the external device in the open drain I/O terminal formation area II is 9 to 12 V. This generates a Fowler-Nordheim (F-N) stress in applying the external power, which can degrade the gate insulating layer 116.

Second, the external power used for operating the external device through the open drain I/O terminal is 9 to 12 V which is relatively higher than the chip operating voltage. As a result, with the conventional device structure, the B•V characteristic of the source/drain junction region 120 is decreased, which can break the junction region in the extreme. This phenomenon often occurs in the part designated “h” in FIG. 2e, where the field insulating doping layer 108 and the active region of the transistors A and B are joined. The I/O pad 20 and the drain are also connected to the active region of the transistors. This problem increases the thinner the gate insulating layer 116 becomes. Therefore, an improvement in this structure is required to solve the problem.

### SUMMARY OF THE INVENTION

Accordingly, the present invention is directed to a semiconductor device having an open drain input/output terminal and its fabricating method that substantially obviates one or more of the problems due to limitations and disadvantages of the related art.

An object of the present invention is to provide a semiconductor device with an open drain input/output (I/O) terminal in which portions of a gate insulating layer in a logic formation area and an open drain I/O formation area are formed to have two different thicknesses. Also, the device is formed such that an active region of each transistor and the field insulating doping layer of the open drain I/O are spaced at a given distance, using a field oxide layer as an intermediate device. This prevents a break in the insulating characteristic of the gate insulating layer generated when applying the external power to each transistor of the open drain I/O and decreases the B•V characteristic of its junction region.

Another object of the invention is to provide a method of effectively fabricating the semiconductor device with the open drain I/O terminal.

Additional features and advantages of the invention will be set forth in the description which follows, and in part will be apparent from the description, or may be learned by practice of the invention. The objectives and other advantages of the invention will be realized and attained by the structure particularly pointed out in the written description and claims, as well as the appended drawings.

To achieve these and other advantages and in accordance with the purpose of the present invention, as embodied and broadly described, a semiconductor device having an open drain input/output terminal, includes: a semiconductor substrate of a first conductivity type, the substrate including an open drain I/O formation area and a logic formation area, a field oxide layer formed over the semiconductor substrate to define a logic active region in the logic formation area and a open drain I/O active region in the open drain I/O formation area, a gate insulating layer formed over the logic active region and the open drain I/O active region, the gate insulating layer being thicker over the open drain I/O active region than over the logic active region, a logic gate electrode formed over the gate insulating layer in the logic active region, and an open drain I/O gate electrode formed over the gate insulating layer in the open drain I/O active region.

The semiconductor device may also include a plurality of junction regions of a second conductivity type formed in the substrate on both sides of the logic gate electrode and the open drain I/O gate electrode, a plurality of field insulating doping layers formed under the field oxide layer, the field insulating doping layers overlapping the junction regions in the logic formation part, and being spaced from the junction regions in the open drain I/O formation part, a first impurity region of the second conductivity type formed in a channel region under the open drain I/O gate electrode, and a second impurity region of the first conductivity type formed in the channel region, between the junction regions. The channel region may be formed in an enhancement transistor formation area in the open drain I/O formation area.

The gate insulating layer may have a multi-layered structure in the open drain I/O active region, including a first gate insulating layer and a second gate insulating layer, and the gate insulating layer may have a single-layered structure in the logic active region, including the second gate insulating layer. Preferably the second gate insulating layer has a thickness in the range of 100 to 140 Å and the first gate insulating layer has a thickness in the range of 90 to 150 Å.

The gate electrode may be formed to have one of a single-layered polysilicon structure or a multi-layered polysilicon/W-silicide structure.

A method of fabricating the semiconductor device with an open drain input/output terminal of the invention is also provided this method includes the steps of: forming a pad oxide layer over a semiconductor substrate of a first conductivity type, the substrate including an open drain I/O formation area and a logic formation area, forming a first anti-oxidation layer over a logic active region in the logic formation area, forming a second anti-oxidation layer over an open drain I/O active region in the open drain I/O formation area, forming a photoresist pattern to surround the second anti-oxidation layer, field-ion implanting a lightly doped first conductivity type impurity ion in an exposed portion of the substrate, removing the photoresist pattern, forming a field oxide layer on the substrate in a device isolation region not covered by the first or second anti-oxidation layers by using a heat-oxidation process, removing the first and second anti-oxidation layers, removing the pad oxide layer in the logic active region and the open drain I/O active region, forming a first gate insulating layer over the substrate in the open drain I/O formation area, and forming a second gate insulating layer over the logic formation area and the open drain I/O formation area.

This method may further include the steps of performing a threshold voltage controlling ion implanting process, after the step of removing the first and second anti-oxidation layers, and performing a threshold voltage controlling ion implanting process after the step of forming the first gate insulating layer.

The photoresist pattern preferably has a thickness of at least 0.4 μm from one side wall of the second anti-oxidation layer. The anti-oxide layer preferably comprises a nitride layer. The first gate insulating layer preferably has a thickness in the range of 90 to 110 Å, and the second gate insulating layer preferably has a thickness in the range of 130 to 140 Å.

The method may also include the steps of forming a sacrificial oxide layer over the logic active region and the open drain I/O active region, forming a second-conductivity-type impurity region of a second conductivity type inside the substrate in the open drain I/O formation area, using a lightly doped impurity ion implanting process, and removing the sacrificial oxide layer. The step of removing the sacrificial oxide layer is preferably performed after the step of forming the second-conductivity-type impurity region.

The method may further include the steps of forming a gate electrode over the second gate insulating layer, forming a source/drain junction region in the substrate on both sides of the gate electrode by implanting highly doped impurity ions of the second conductivity type, and forming a first-conductivity-type impurity region of the first conductivity type in the impurity region using a lightly doped impurity ion implanting process.

The gate electrode preferably has one of a single-layered polysilicon structure or a multi-layered polysilicon/W-silicide structure.

With a semiconductor device and fabrication method as described, the invention provides the following effects. First, since the gate insulating layer of the transistors that form the open drain I/O terminal are thicker than those in the logic transistor, the gate insulating layer will not be degraded, even though a high external power voltage is applied to the drain of each transistor in the open drain I/O. This prevents the break of the device's insulating characteristic.

Second, the field insulating doping layer and the junction region for the source/drain are structured to be separated by a given distance in the open drain I/O formation area. As a result, when applying the external high voltage, the internal pressure of the junction region is raised, which prevents any decrease of the B•V characteristic of the junction.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a circuit diagram illustrating the structure of an open drain input/output terminal of a related semiconductor device;

FIGS. 2a to 2e illustrate the procedure for fabricating a semiconductor device with an open drain input/output terminal, as shown in FIG. 1; and

FIGS. 3a to 3g illustrate the procedure for fabricating a semiconductor device with an open drain input/output terminal in accordance with a preferred embodiment of the present invention.

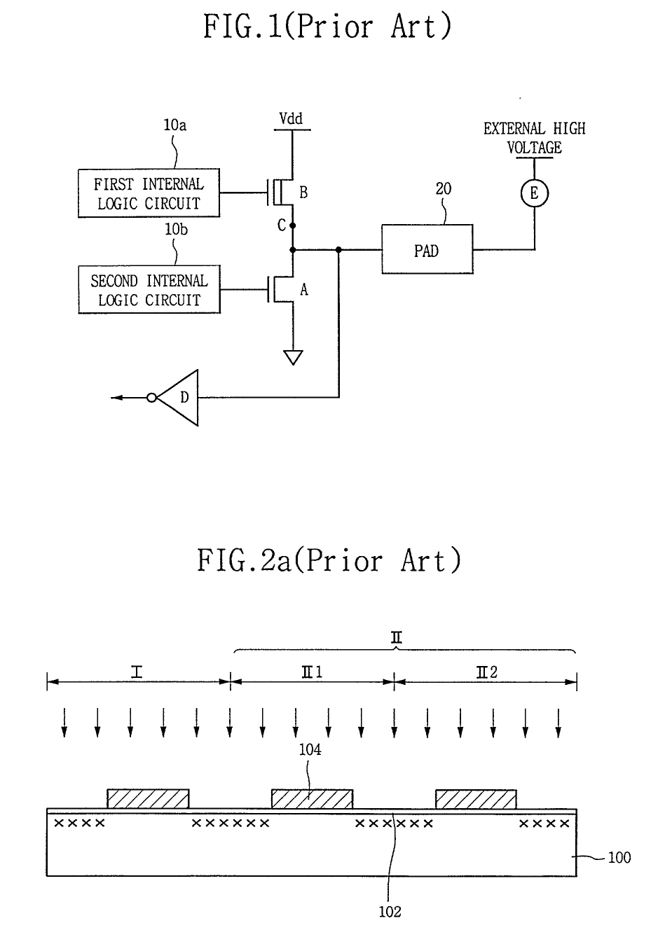

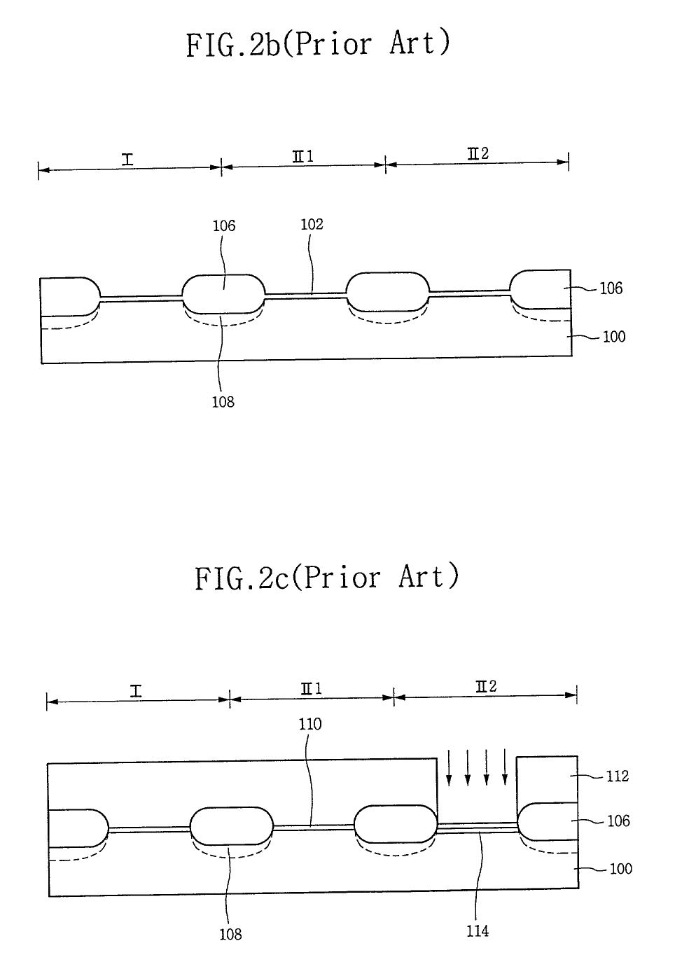

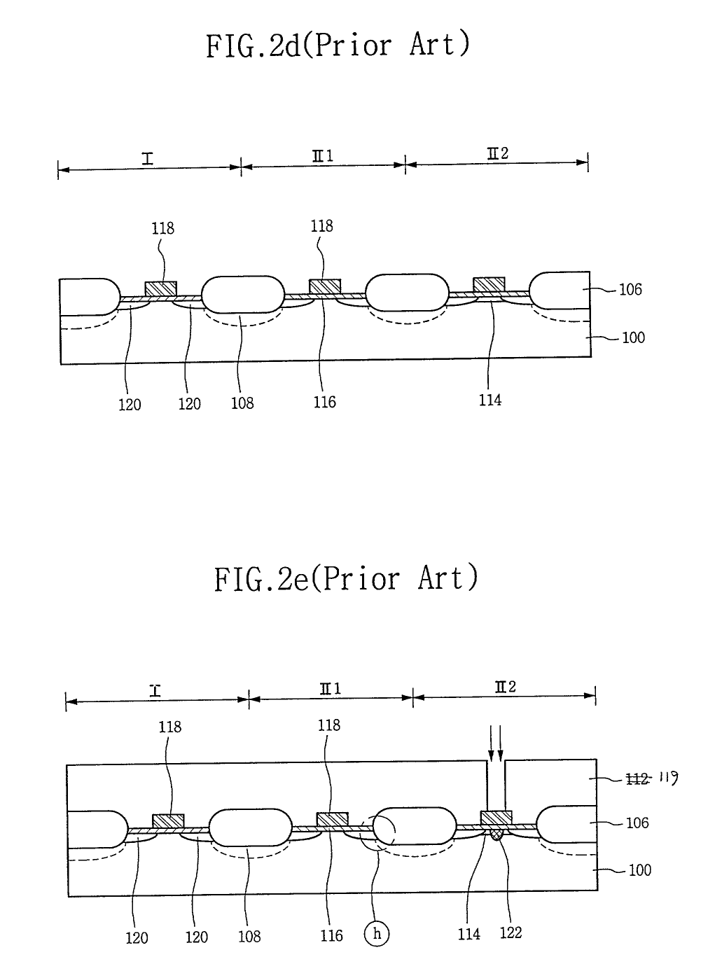

### DETAILED DESCRIPTION OF PREFERRED EMBODIMENT

Reference will now be made in detail to a preferred embodiment of the present invention, an example of which is illustrated in the accompanying drawings.

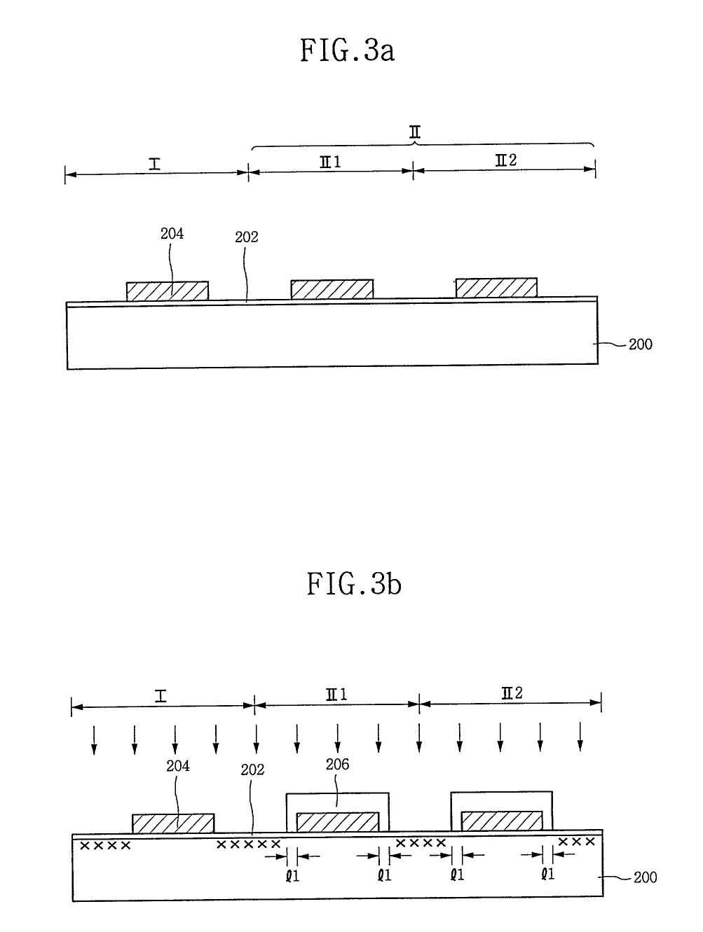

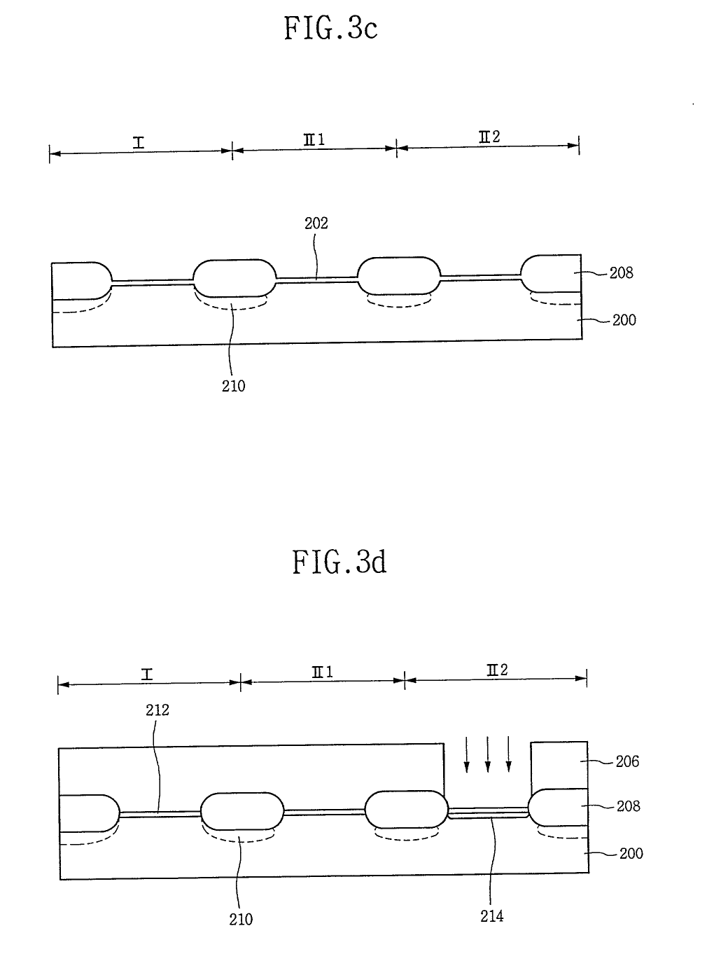

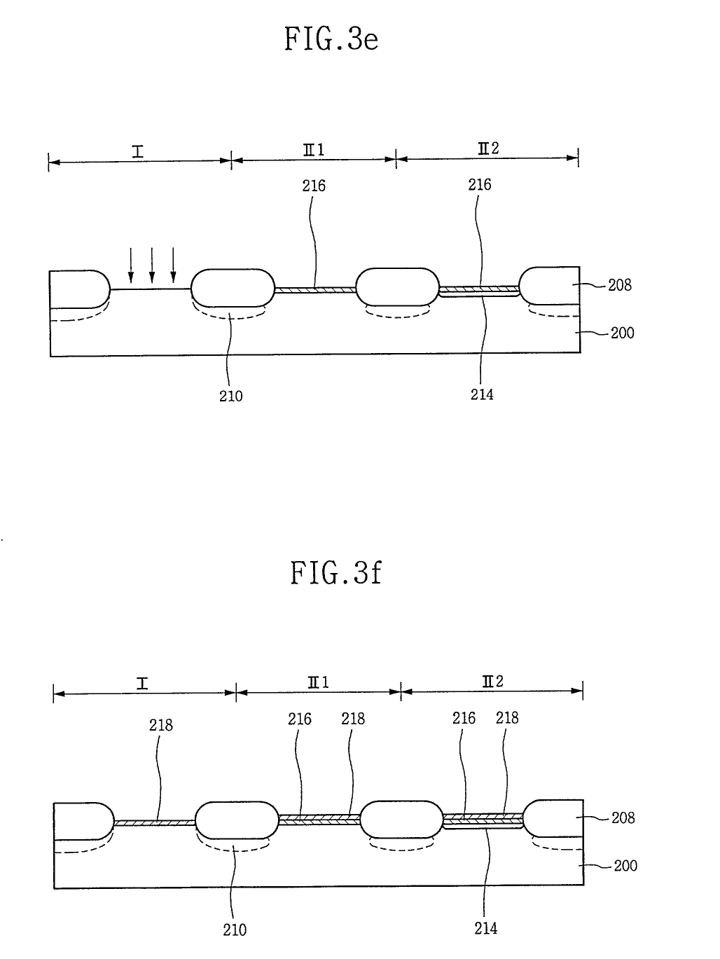

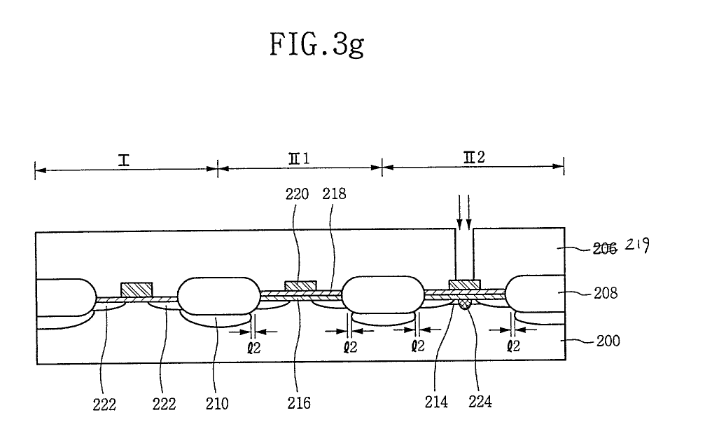

The invention acts to prevent the degradation of a gate insulating layer with a corresponding decrease in B•V characteristics in a junction region, generated when applying the external high voltage to the drain of each transistor of an open drain I/O terminal. This is achieved by forming a gate insulating layer for transistors of an open drain I/O that is thicker than that formed for a logic transistor and a field insulating doping layer and by separating the junction regions of the open drain I/O terminal from each other at a predetermined distance. It is also achieved by having a field oxide layer at its center in the border face of the active region and the device isolating region. The method will be described below with reference to FIGS. 3a to 3g.

FIGS. 3a to 3g illustrate a procedure for fabricating a semiconductor device with an open drain input/output terminal in accordance with a preferred embodiment of the present invention. For the sake of convenience, the method will be described in seven steps. In addition, although the method will be described specifically with respect to NMOS transistors, it should be understood that the procedures can be easily applied to PMOS transistors as well.

In the first step, as illustrated in FIG. 3a, a pad oxide layer 202 and an anti-oxidation layer 204 are sequentially formed over an active region of a first conductivity type semiconductor substrate, e.g., p-type. The anti-oxidation layer 204 preferably comprises a nitride layer. Reference number “I” designates a logic formation area, while reference number “II” designates an open drain I/O terminal comprising an open drain transistor formation area II₁ and an enhancement transistor formation area II₂.

In the second step, as illustrated in FIG. 3b, a first photoresist pattern 206 is formed over and to the side of the anti-oxidation layer 204 in the open drain I/O formation area II to surround the overall surface of the anti-oxidation layer 204 in the open drain I/O formation area II.

A lightly-doped first conductivity type impurity ion is then implanted in the substrate 200 using the anti-oxidation layer 204 and the first photoresist pattern 206 as an implantation mask. In FIG. 3b, the region where the impurity ion is implanted, i.e., a field insulating doping region, is marked by the letter “x.” Because of the presence of the first photoresist pattern 206, the field insulating doping region is separated from the anti-oxidation layer 204 in the open drain I/O formation area II by a distance l₁. The first photoresist pattern 206 is preferably formed to keep the distance l₁ longer than 0.4 μm.

The reason for implanting the field-ion into the substrate 200 such that a portion of the device isolating region is covered with the first photoresist pattern 206 is to prevent the formation of the field insulating doping layer under the field oxide layer at the junction area of the active region and the device isolating region. This can prevent the joining of the junction and the field insulating doping region at their border face when forming the junction region for the source and drain.

In the third step, as illustrated in FIG. 3c, the first photoresist pattern 206 is removed and an oxidation process is performed using the anti-oxidation layer 204 as a mask to form a field oxide layer 208 having a field insulating doping layer 210. The anti-oxide layer 204 is then removed and a threshold voltage controlling an ion implanting process is performed. As shown in FIG. 3c, the field insulating doping layer 210 is formed all of the way under the field oxide layer 208 in the logic formation area I. In contrast, the field insulating doping layer 210 is formed only under the center portion of the field oxide layer 208 in the open drain I/O formation area II, not along the edges.

In the fourth step, as illustrated in FIG. 3d, the pad oxide layer 202 in the active region is removed and a sacrificial oxide layer 212 is formed over the substrate 200. A photoresist layer of a predetermined thickness is then formed over the overall surface of the substrate 200. Thereafter, using the photo-etching process, the photoresist layer is selectively etched to expose the surface of the sacrificial oxide layer 212 over the enhancement transistor formation part II₂. A lightly-doped second conductivity type impurity ion, e.g., of n-type, is implanted in the exposed sacrificial oxide layer 212, to form a second-conductivity-type impurity region 214 in the substrate 200. The second-conductivity-type impurity region 214 will be used as a depletion region for the enhancement transistor formed in the enhancement transistor formation part II₂.

The second-conductivity-type impurity region 214 can be formed in such a manner that the pad oxide layer 202 in the active region is removed, the sacrificial oxide layer 212 is formed over the substrate 200 and is then removed in the enhancement transistor formation part II₂, and the second conductivity type impurity ion is implanted in the enhancement transistor formation part II₂.

In the fifth step, as illustrated in FIG. 3e, the photoresist pattern 206 and the sacrificial oxide layer 212 are sequentially removed. A first gate insulating layer 216 is formed over a portion of the substrate 200 not covered by the sacrificial oxide layer 208, preferably in the range of 90 to 150 Å in thickness. The first gate insulating layer 216 in the logic formation area I is then removed to expose the surface of the substrate 200, and a threshold voltage controlling ion implanting process is preferably performed. The threshold voltage controlling ion implanting process can be skipped, if desired. The reason that this process may be repeated, however, is to control the difference of the threshold voltage between the transistors, e.g. between the transistors forming the logic transistor and those forming the open drain I/O terminal, which is caused by the difference of thickness of the gate insulating layer. This control can be achieved through the use of an additional threshold voltage controlling ion implanting process with respect to the logic transistor.

In the sixth step, as illustrated in FIG. 3f, a second gate insulating layer 218 is formed over the exposed surface of the substrate 200 in the logic formation area I and the open drain I/O formation area II, preferably in the range of 100 to 140 Å in thickness. As a result, a single gate insulating layer (comprising the second gate insulating layer 218) in the range of 100 to 140 Å in thickness is formed in the logic formation area I, while a double gate insulating layer (comprising the first and second gate insulating layers 216 and 218) having a thickness of 220 to 250 Å is formed in the open drain I/O formation area II.

The reason for forming the gate insulating layer in the open drain I/O formation area II to be thicker than that in the logic formation area I is to prevent the gate insulating layer from being degraded due to a high voltage, e.g., 9 to 12 V, when the external voltage is applied to each transistor of the open drain I/O terminal.

In the seventh step, as illustrated in FIG. 3g, a plurality of gate electrodes 220, preferably made to have a single layered polysilicon structure or a multi-layered polysilicon/W-silicide structure, are formed over a predetermined portion of the second gate insulating layer 218. Heavily doped second conductivity type impurity ions are then implanted in the substrate 200 using the gate electrodes 220 as a mask. These heavily doped second conductivity type impurity ions form a junction region 222 that will be used for a source and drain inside the substrate 200 on both sides of each of the gate electrodes 220.

In the logic formation area I, the junction region 222 and the field insulating doping layer 210 join with each other at the border face of the active region and the device isolating region.

In the open drain I/O formation area II, however, the junction region 222 and the field insulating doping layer 210 are spaced apart by a predetermined distance of l₂ from their border face. By spacing them at a predetermined distance, the internal pressure of the junction region 222 can be raised so that even when a high voltage is applied to them, the B•V characteristic of the junction region for the source/drain is not decreased.

A photoresist layer is formed over the second gate insulating layer 218 including the field insulating layer 208 and the gate electrode 220. The layer is selectively etched by a photo-etching process to expose a predetermined portion of the gate electrode 220 in the enhancement transistor formation area 112, thereby forming a second photoresist pattern 219. A lightly-doped second conductivity type impurity ion is implanted with a high energy in the exposed surface of the gate electrode 220, thereby forming a first-conductivity-type impurity region 224 inside the second-conductivity-type impurity region 214.

The reason for forming the first-conductivity-type impurity region 224 inside the second-conductivity-type impurity region 224 is as follows. If only the second-conductivity-type impurity region 214 were formed in the channel region, the impurity region 214 would operate as a depletion transistor and always have the “ON” characteristic unless an inverse-bias signal is applied to it. This would make it difficult to control the external device. Instead, it is preferable that the transistor be converted into an enhancement transistor, which always maintains the “OFF” characteristic unless a high level signal is applied to it, to be used in the external device operation. As a result, a general logic transistor is formed in the logic formation area I and the open drain transistor and the enhancement transistor are formed in the open drain I/O formation area II.

Thereafter, the second photoresist pattern 219 is removed and an insulating interlayer (not shown) having a contact hole is formed over the overall surface of the substrate 200. A metallization layer (not shown) is formed to join the gate electrode 220 and the junction region 222, completing the process.

Accordingly, gate insulating layers are formed to have a different thickness from each other in the logic formation area I and in the open drain I/O formation area II in the active region of a substrate 200 of a first conductivity type, having the field oxide layer 208.

A plurality of gate electrode 220 are formed over a predetermined portion of the gate insulating layer. Junction regions 222 for source/drain is formed in the substrate 200 on both sides of each of the gate electrodes 220. In the logic formation area I under the field oxide layer 208, the junction region 222 and the field insulating doping layer 210 overlap at a predetermined portion. In the open drain I/O formation area II, the junction region 222 and the field insulating doping layer 210 are spaced apart from each other by a predetermined distance. In addition, the second-conductivity-type impurity region 214 is formed the channel region of the enhancement transistor formation area II₂. The first-conductivity-type impurity region 224 is formed within the impurity region 214, thus fabricating the semiconductor device with the above-structured open drain I/O terminal.

The gate insulating layer, as described above, is fabricated to have a single-layer structure in the logic formation area I (including the second gate insulating layer 218), and to have the multi-layered structure in the open drain I/O formation area II (including the first gate insulating layer 216 and the second gate insulating layer 218) As a result, the resulting device has a relatively thicker gate insulating layer in the open drain I/O formation area II.

As described above, the invention provides the following effects. First, since the gate insulating layers for the transistors that form the open drain I/O are thicker than the gate insulating layers in the transistors that form the logic transistors, the gate insulating layer is not degraded, even though the high voltage of external power is applied to the drain of each transistor in the open drain I/O. This prevents the break of the transistors' insulating characteristics. Second, the field insulating doping layer and the junction region for the source/drain are structured to be separated by a predetermined distance, having the field oxide layer at its center in the border face of the active region and the device isolating region in the open drain I/O. As a result, when applying the external high voltage, the internal pressure of the junction region is raised, which prevents a decrease of the B•V characteristic of the junction.

It will be apparent to those skilled in the art that various modifications and variations can be made in the semiconductor device with the open drain I/O and its fabricating method of the present invention without departing from the spirit or scope of the invention. I is intended that the present invention cover such modifications and variations of this invention, provided they come within the scope of the appended claims and their equivalents.

What is claimed is:

1. A semiconductor device having an open drain input/output terminal, comprising:
a semiconductor substrate of a first conductivity type, the substrate including an open drain I/O formation area and a logic formation area;
a field oxide layer formed over the semiconductor substrate to define a logic active region in the logic formation area and a open drain I/O active region in the open drain I/O formation area;
a gate insulating layer formed over the logic active region and the open drain I/O active region, the gate insulating layer being thicker over the open drain I/O active region than over the logic active region;
a logic gate electrode formed over the gate insulating layer in the logic active region; and
an open drain I/O gate electrode formed over the gate insulating layer in the open drain I/O active region.

2. A semiconductor device having an open drain input/output terminal, as recited in claim 1, further comprising:
a plurality of junction regions of a second conductivity type formed in the substrate on both sides of the logic gate electrode and the open drain I/O gate electrode;
a plurality of field insulating doping layers formed under the field oxide layer, the field insulating doping layers overlapping the junction regions in the logic formation part, and being spaced from the junction regions in the open drain I/O formation part;
a first impurity region of the second conductivity type formed in a channel region under the open drain I/O gate electrode; and
a second impurity region of the first conductivity type formed in the channel region, between the junction regions.

3. A semiconductor device having an open drain input/output terminal, as recited in claim 2, wherein the channel region is formed in an enhancement transistor formation area in the open drain I/O formation area.

4. A semiconductor device having an open drain input/output terminal, as recited in claim 1,
wherein the gate insulating layer has a multi-layered structure in the open drain I/O active region, including a first gate insulating layer and a second gate insulating layer, and
wherein the gate insulating layer has a single-layered structure in the logic active region, including the second gate insulating layer.

5. A semiconductor device having an open drain input/output terminal, as recited in claim 4, wherein the second gate insulating layer has a thickness in the range of 100 to 140 Å.

6. A semiconductor device having an open drain input/output terminal, as recited in claim 4, wherein the first gate insulating layer has a thickness in the range of 90 to 150 Å.

7. A semiconductor device having an open drain input/output terminal, as recited in claim 4, wherein the gate electrode is formed to have one of a single-layered polysilicon structure or a multi-layered polysilicon/W-silicide structure.

8. A method of fabricating the semiconductor device with an open drain input/output terminal, comprising:
forming a pad oxide layer over a semiconductor substrate of a first conductivity type, the substrate including an open drain I/O formation area and a logic formation area;
forming a first anti-oxidation layer over a logic active region in the logic formation area;
forming a second anti-oxidation layer over an open drain I/O active region in the open drain I/O formation area;
forming a photoresist pattern to surround the second anti-oxidation layer;
field-ion implanting a lightly doped first conductivity type impurity ion in an exposed portion of the substrate;
removing the photoresist pattern;
forming a field oxide layer on the substrate in a device isolation region not covered by the first or second anti-oxidation layers by using a heat-oxidation process;
removing the first and second anti-oxidation layers;
removing the pad oxide layer in the logic active region and the open drain I/O active region;
forming a first gate insulating layer over the substrate in the open drain I/O formation area; and
forming a second gate insulating layer over the logic formation area and the open drain I/O formation area.

9. A method of fabricating the semiconductor device with an open drain input/output terminal, as recited in claim 8, further comprising performing a threshold voltage controlling ion implanting process, after the step of removing the first and second anti-oxidation layers.

10. A method of fabricating the semiconductor device with an open drain input/output terminal, as recited in claim 9, further comprising performing a threshold voltage controlling ion implanting process after the step of forming the first gate insulating layer.

11. A method of fabricating the semiconductor device with an open drain input/output terminal, as recited in claim 8, wherein the photoresist pattern has a thickness of at least 0.4 μm from one side wall of the second anti-oxidation layer.

12. A method of fabricating the semiconductor device with an open drain input/output terminal, as recited in claim 8, wherein the anti-oxide layer comprises a nitride layer.

13. A method of fabricating the semiconductor device with an open drain input/output terminal, as recited in claim 8, wherein the first gate insulating layer has a thickness in the range of 90 to 110 Å.

14. A method of fabricating the semiconductor device with an open drain input/output terminal, as recited in claim 8, wherein the second gate insulating layer has a thickness in the range of 130 to 140 Å.

15. A method of fabricating the semiconductor device with an open drain input/output terminal, as recited in claim 8, further comprising:
forming a sacrificial oxide layer over the logic active region and the open drain I/O active region;
forming a second-conductivity-type impurity region of a second conductivity type inside the substrate in the open drain I/O formation area, using a lightly doped impurity ion implanting process; and
removing the sacrificial oxide layer.

16. A method of fabricating the semiconductor device with an open drain input/output terminal, as recited in claim 15, wherein the step of removing the sacrificial oxide layer is performed after the step of forming the second-conductivity-type impurity region.

17. A method of fabricating the semiconductor device with an open drain input/output terminal, as recited in claim 15, further comprising:
forming a gate electrode over the second gate insulating layer;
forming a source/drain junction region in the substrate on both sides of the gate electrode by implanting highly doped impurity ions of the second conductivity type; and
forming a first-conductivity-type impurity region of the first conductivity type in the impurity region using a lightly doped impurity ion implanting process.

18. A method of fabricating the semiconductor device with an open drain input/output terminal, as recited in claim 17, wherein the gate electrode has one of a single-layered polysilicon structure or a multi-layered polysilicon/W-silicide structure.
